(19) United States
(12) Patent Application Publication
(10) Pub. No.: US 2015/0118861 A1
(43) Pub. Date: Apr. 30, 2015

(54) CZOCHRALSKI SUBSTRATES HAVING REDUCED OXYGEN DONORS

(71) Applicant: Texas Instruments Incorporated, Dallas, TX (US)

(72) Inventors: BRADLEY DAVID SUCHER, MURPHY, TX (US); RICK L. WISE, FAIRVIEW, TX (US); SCOTT GERARD BALSTER, DALLAS, TX (US); SEUNG-SA PARK, IBARAKI (JP); PHILIP LELAND HOWER, CONCORD, MA (US); JOHN LIN, CHELMSFORD, MA (US); GURU MATHUR, PLANO, TX (US); YONGXI ZHANG, PLANO, TX (US)

(21) Appl. No.: 14/521,138

(22) Filed: Oct. 22, 2014

Related U.S. Application Data
(60) Provisional application No. 61/896,232, filed on Oct. 28, 2013.

(51) Int. Cl. H01L 21/322; C30B 33/00; H01L 21/02; C30B 33/02

(52) U.S. Cl. CPC H01L 21/3225; C30B 33/02; C30B 33/005; H01L 21/02164; H01L 21/02236
USPC 438/770

(57) ABSTRACT

A method of semiconductor fabrication includes providing an unpatterned lightly doped Czochralski bulk silicon substrate (LDCBS substrate) having a concentration of oxygen atoms of at least (≧) 10¹⁷ atoms/cm³ with a boron doping or n-type doping concentration of between 1×10¹² cm⁻³ and 5×10¹⁴ cm⁻³. Before any oxidization processing, the LDCBS substrate is annealed at a nucleating temperature between 550° C. and 760° C. for a nucleating time that nucleates the oxygen atoms in a sub-surface region of the LDCBS substrate to form oxygen precipitates therefrom. After the annealing, a surface of the LDCBS substrate or an epitaxial layer on the surface of the LDCBS substrate is initially oxidized in an oxidizing ambient at a peak temperature of between 800° C. and 925° C. for a time less than or equal (≦) to 30 minutes.

### CROSS REFERENCE TO RELATED APPLICATIONS

This application claims the benefit of Provisional Application Ser. No. 61/896,232 entitled “THERMAL BUDGET ENHANCEMENT TO ELIMINATE/MINIMIZE OXYGEN ACTING AS A THERMAL DONOR IN LIGHTLY DOPED BORON SILICON”, filed Oct. 28, 2013, which is herein incorporated by reference in its entirety.

### FIELD

Disclosed embodiments relates to semiconductor fabrication using lightly doped single crystal Czochralski silicon substrates.

### BACKGROUND

The Czochralski process is a method of crystal growth commonly used to obtain single crystals of certain semiconductors (e.g., silicon, germanium and gallium arsenide), and some other metals such as certain synthetic gemstones. When silicon is grown by the Czochralski method to fabricate “Czochralski silicon”, silicon is melted in a quartz glass crucible, and a monocrystalline (single crystal) silicon seed crystal is dipped into the melt and continued lifting of the seed crystal away from the surface of the melt is utilized. In the course of this movement, the single crystal grows at a phase boundary that has formed between the melt and the lower end of the seed crystal during the process of dipping the seed crystal. During Czochralski silicon crystal growth, the walls of the crucible dissolve into the melt and Czochralski silicon therefore contains a significant concentration of oxygen typically being at a concentration level of about 10¹⁸ cm⁻³, virtually all of which is interstitial, i.e., between silicon lattice sites.

Oxygen in silicon wafers is known to provide beneficial effects, including intrinsic gettering of metals known to reduce minority carrier lifetime which increases junction leakage. In a commonly used substrate arrangement, the substrate includes a topmost denuded zone to be used as active area which is clear of most defects and is thin enough to enable a deep or internal region below the denuded zone which contains a high concentration of crystalline defects to provide the intrinsic gettering effect. The deep or internal region below the denuded zone contains a high concentration of crystalline defects including oxygen precipitates such as bulk micro defects (BMDs) having a size or concentration large enough to allow an increase of the intrinsic gettering effect in substrates sufficient to reduce device leakage and associated device failures. For example, to form a denuded zone, oxygen can be caused to diffuse out of the surface of the substrate by heat-treating (e.g. annealing) silicon wafers in a furnace at relatively high temperatures, for example, at 1000° C. to 1200° C., generally under an inert gas atmosphere.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments recognize wafer fabrication processing using lightly doped bulk Czochralski silicon comprising substrates (LDCBS substrates) to provide high junction breakdown voltages that have denuded zones can result in interstitial oxygen in the silicon several microns below the top substrate surface (hereafter the sub-surface) getting into the silicon lattice and thus becoming extra donors (n-type) in the finished device. The extra donors provided by the O atoms can be at a concentration high enough to sufficiently change the net doping level in the lightly doped substrate and thus affect the performance of the finished device.

The LDCBS substrate doping can be boron doping or n-type doping. The doping level for either lightly doped boron or lightly n-type doped is generally between 1×10⁻¹² cm⁻³ and 5×10¹⁴ cm⁻³. For a boron LDCBS substrate, <5×10¹⁴ cm⁻³ corresponds to a 25° C. bulk resistivity of about 30 ohm-cm. For such LDCBS substrates, interstitial oxygen therein can become oxygen donors in the silicon lattice which cause the substrate in the case of a lightly boron doped substrate in the sub-surface to become reduced in net boron doping (higher resistivity) including in some cases changing from p-type to n-type (a buried n-type inversion). Buried n-type inversion for LBCBS substrates is recognized to cause the discrete device or integrated circuit (IC) to have degraded performance or fail, including causing leakage problems.

For an n-type LDCBS substrate, oxygen donors cause the sub-surface to become significantly more highly n-doped (lower resistivity) which can result in lowered junction breakdown voltages. Disclosed embodiments recognize a pre-oxidation anneal (before any oxidation processing) at the beginning of the process flow can be important to form oxygen precipitates (such as to form bulk micro defects (BMDs)) in the sub-surface sufficient so that the oxygen interstitials are consumed by the pre-oxidation anneal and thus essentially no longer available in the silicon in the interstitial form that allows oxygen atoms entering the silicon lattice and acting as thermal donors later in the fabrication process in a sufficient enough concentration to affect operation of the final (completed) device or IC.

Disclosed embodiments include methods of semiconductor fabrication including providing an unpatterned (no topography) LDCBS substrate (e.g., wafer) having a concentration of oxygen atoms of at least (≧) 10¹⁷ atoms/cm³ with a boron doping or n-type doping concentration of <5×10¹⁴ cm⁻³, generally between 1×10¹² cm⁻³ and 5×10¹⁴ cm⁻³. The LDCBS substrate is pre-oxidation annealed (before any oxidization processing) at a nucleating temperature between 550° C. and 760° C. for a nucleating time that nucleates the oxygen atoms to form oxygen precipitates therefrom in the sub-surface of the substrate.

After the annealing, a surface of the LDCBS substrate is initially oxidized in an oxidizing ambient at a peak temperature of between 800° C. and 925° C. for a time less than or equal (≦) to 30 minutes which is recognized to minimize growth of the oxygen precipitates (e.g., BMD growth) which if allowed to grow can cause crystal defects that reach proximate to the top surface of the substrate where the active devices are formed. It is also recognized above about 900° C. as a target temperature, ramp rates typically slow down such that undesired BMD growth during temperature ramp up/down can become significant. The resulting peak oxygen precipitate concentration in the sub-surface of the LDCBS substrate is generally at least 1×10⁷ cm⁻³.

### BRIEF DESCRIPTION OF THE DRAWINGS

Reference will now be made to the accompanying drawings, which are not necessarily drawn to scale, wherein:

FIG. 1 is a flow chart that shows steps in an example method of semiconductor fabrication including before any oxidization processing annealing a LDCBS substrate to nucleate oxygen atoms to form sub-surface oxygen precipitates therefrom, and then initially oxidizing a surface of the LDCBS substrate, according to an example embodiment.

FIG. 2 is a temperature vs. time plot for an example annealing and initial oxidizing furnace cycle including an oxygen precipitating annealing step at about 650° C. followed by an initial oxidation, according to an example embodiment.

FIG. 3 shows comparative electrical results (breakdown voltage, BV) obtained from LDMOS transistors on test structures for completed IC product when a known annealing then initial oxidation step (shown as “baseline”) was used and when a disclosed annealing then initial oxidation step was used shown as “Nucleation” (the example method with its temperature vs. time plot depicted in FIG. 2).

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

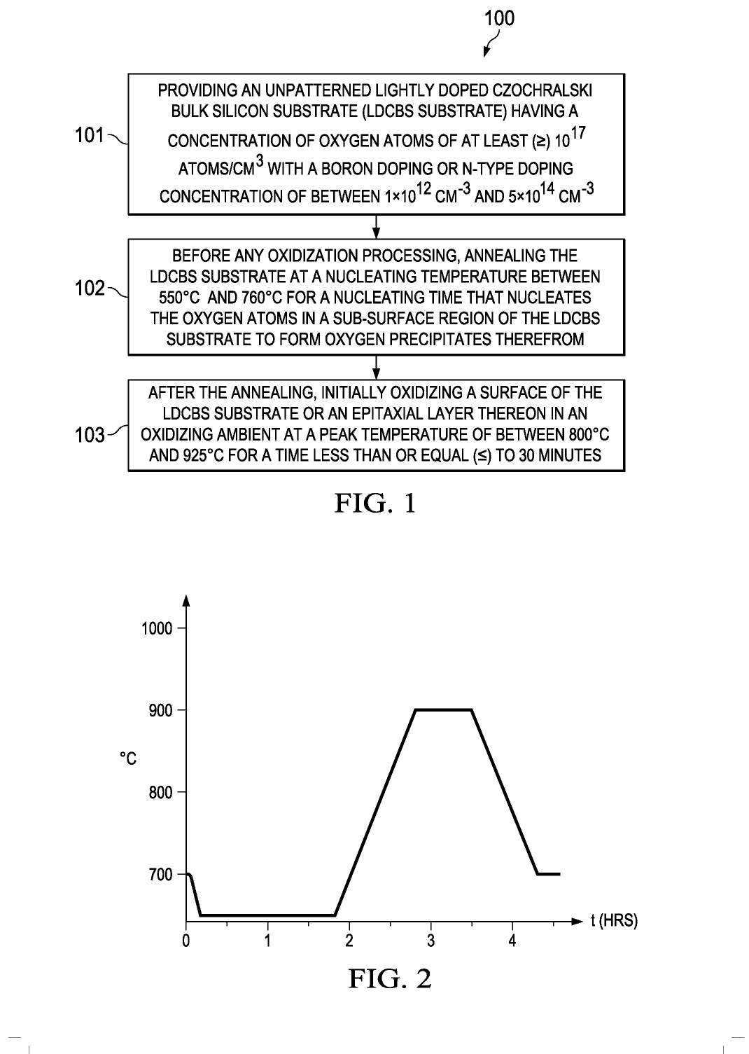

FIG. 1 is a flow chart that shows steps in an example method 100 of semiconductor fabrication including before any oxidization processing annealing a LDCBS substrate (e.g., wafer) to nucleate oxygen atoms to form sub-surface oxygen precipitates therefrom sufficient to largely reduce later process generating oxygen thermal donors, according to an example embodiment. Step 101 comprises providing an unpatterned LDCBS substrate (e.g., wafer) having a concentration of oxygen atoms of at least (≧) 10¹⁷ atoms/cm³ with a boron doping or n-type doping concentration of between 1×10¹² cm⁻³ and 5×10¹⁴ cm ⁻³. The low doping concentration as known in the art when used in the lightly doped side of a pn junction enables formation of pn junctions having high breakdown voltages.

The LDCBS substrate can comprise bulk silicon, or certain silicon compounds. Optionally, the LDCBS substrate can have an optional epitaxial layer thereon, which will generally have no impact on disclosed methods. The substrate may also comprise a silicon alloy such as silicon germanium, or silicon germanium carbide. The LDCBS substrate surface may also contain approximately 1×10¹³ cm⁻³ to ×10¹⁴ cm⁻³ nitrogen.

In the case of a boron doped LDCBS substrate, oxygen donors in silicon can cause the LDCBS substrate to increase in resistivity (due to compensation by oxygen donors) and in some cases change from p-type to n-type (an n-type inversion). Buried n-type inversion for boron doped LDCBS substrates is recognized to cause the discrete device or integrated circuit (IC) to fail including causing leakage problems. The inversion typically does not occur until it transitions out of the denuded zone so there is normally some substrate material near the surface that remains p-type. For one particular high voltage analog IC product, the substrate properties generally remain relevant to depths greater than the first 10 microns.

For n-type doped LDCBS silicon substrates, oxygen donors cause more highly n-doped (lower resistivity) layers which can result in lowered junction breakdown voltages. For devices such as Insulated Gate Bipolar Transistors (IGBTs) or PIN diodes (e.g., 600V or above up to several thousand volts) an oxygen induced increase in n-type doping level can result in lower breakdown voltage induced device failures.

Step 102 comprises before any oxidization processing on the LDCBS substrate, annealing the LDCBS substrate at a nucleating temperature between 550° C. and 760° C. for a nucleating time that nucleates (precipitates) a majority of the interstitial oxygen atoms in a sub-surface region of the LDCBS substrate to form oxygen precipitates therefrom. The ambient for step 102 is generally an inert ambient or largely inert ambient, such as nitrogen, argon, or a diluted oxygen ambient such as nitrogen plus <10% oxygen in one example. One particular embodiment is 2 hours at 650° C. in an inert ambient. Step 102 can be performed as a separate step in the flow, or as part of a combined annealing (step 102) and initial oxidation (step 103) single furnace operation.

As used herein, a “furnace” used for disclosed oxidizing and annealing is defined to have its conventional meaning, that being a long tube heated over a large process zone (>0.5 m) that accommodates multiple semiconductor wafers (one or more lots) at a time, where the total process time from loading to unloading is generally at least 0.5 hrs, and that attainable temperature ramp rate is generally <20° C./min. Furnace processing may be distinguished from Rapid Thermal Processing (or RTP) which refers to a semiconductor manufacturing process which heats single wafers to high temperatures (up to 1,050° C. or greater) on a timescale of several minutes or less, where the rapid heating rates are often attained by high intensity lamps or lasers.

The resulting oxygen precipitates are distributed as a function of depth from the top surface of the LDCBS substrate below a denuded zone that is generally at least 5 μm and up to 20 μm thick having a denuded zone thickness depending on a plurality of factors including crystal growth properties (silicon interstitials versus vacancies), vacancy agglomerates in the form of Crystal Originated Pits (COPs), oxygen concentration, presence/concentration of nitrogen doping, and temperature cycles.

Formation of the oxygen precipitates such as BMDs in a sub-surface of the LDCBS substrate are in a concentration sufficient to reduce the oxygen donor concentration resulting from later processing in the completed circuit. For example, by adding an interstitial oxygen precipitate/nucleation step at a temperature between 550° C. and 760° C. (e.g., 575° C. to 690° C.) before the first oxidation step seen by the LDCBS substrate, at least a majority of the oxygen interstitials are consumed to form oxygen precipitates, so they are no longer available to act as thermal donors triggered by processing later in the process flow, such as resulting from a metal sinter process performed at about 435° C. which is recognized to correspond to near a peak temperature for the oxygen donor generation rate. The peak concentration of oxygen precipitates within the sub-surface portion of the LDCBS substrate after step 102 is generally at least 1×10⁷ cm⁻³, such as a peak concentration of 1×10⁸ cm⁻³ being at a depth of 10 μms in one particular embodiment.

Step 103 comprises after annealing, initially oxidizing a surface of the LDCBS substrate or an epitaxial layer thereon in an oxidizing ambient at a peak temperature of between 800° C. and 925° C. for a time less than or equal (≦) to 30 minutes. One particular cycle is 20 minutes at 900° C. in steam. The oxidizing ambient can comprise steam. This step minimizes the time at temperature part of the initial oxidation step to the LDCBS substrate which has been found to advantageously do little for oxygen precipitate (e.g., BMD) growth to the point that it cannot be measured by normal techniques. In contrast, conventional initial oxidations cycles such as a dry oxidation at 900° C. to 1,000° C. for 1 to 2 hours has been recognized to act as an oxygen precipitate (e.g., BMD) growth step, which can result in excessive precipitation leading to formation of crystal dislocations in the device active region causing leakage or shorts.

Following steps 102 and 103, a pad nitride can be used for a shallow trench isolation (STI) process which may be deposited. This nitride is typically deposited using an LPCVD process. Additional front end of the line (FEOL) processing generally takes place, including lithography, etching, ion implantation and a plurality of heat cycles after the annealing including steps to form active circuitry on and in the LDCBS surface or an epitaxial surface thereon configured for providing a circuit function, to build the transistors and other components and to build the interconnection layers needed to complete the IC.

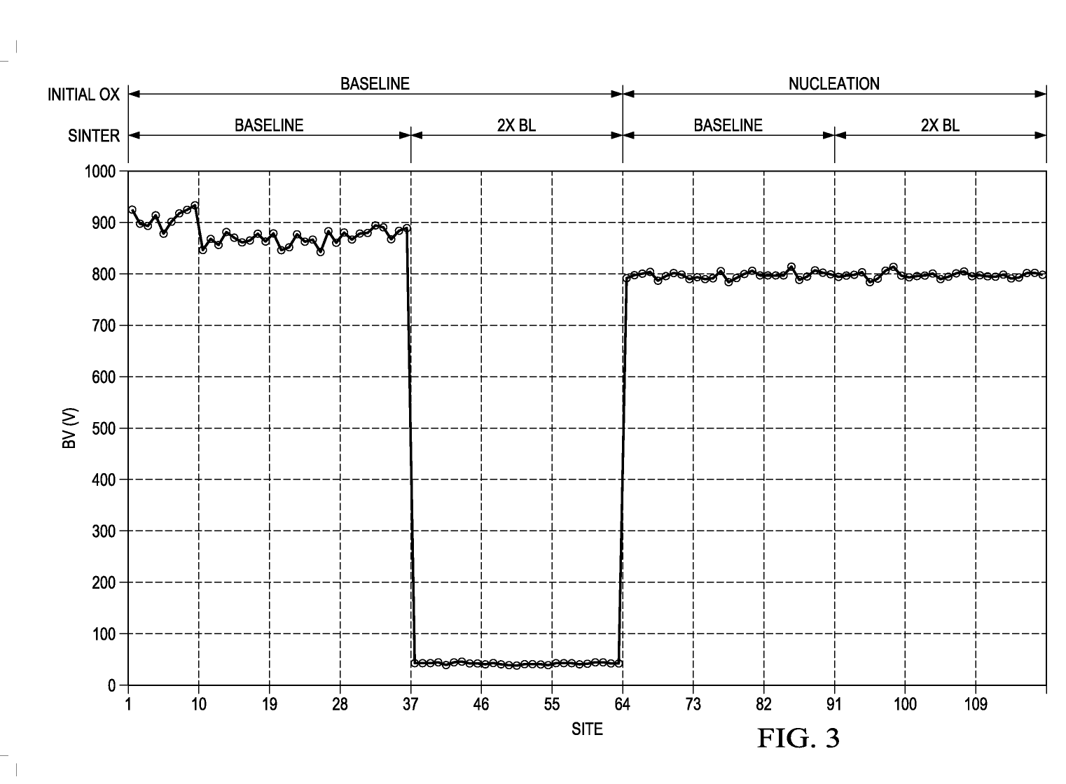

FIG. 2 is a temperature (in ° C.) vs. time plot for an example annealing and initial oxidizing furnace cycle including an oxygen precipitating annealing step at about 650° C. followed by an initial oxidation, according to an example embodiment. The process shown includes an initial oxidation step at about 650° C. for 2 hours that provides oxygen precipitation, followed by a ramp up to 900° C., and an initially oxidization in steam for 20 minutes at 900° C., followed by a ramp down to 700° C. As described above, this oxidation minimizes the time at temperature part of the initial oxidation step to the LDCBS substrate which has been found to advantageously do little for oxygen precipitate (e.g., BMD) growth to the point that it cannot be measured by normal techniques.

Certain high voltage analog IC processes utilize a LDCBS substrate that is so lightly boron doped that if the interstitial oxygen does not go through an oxygen nucleation cycle early in the process flow, it has been found that the remaining interstitial oxygen at the end of the line processing such as at the 400-450° C. alloy processing step will enter the lattice and thus act as thermal donors which can change the silicon in the sub-surface from being p-type to being n-type. Starting material changes alone, such as the addition of a thin epitaxial layer and change in crystal growth to influence the concentration of silicon vacancies, did not resolve the O donor issue (causing buried n-type inversion). Disclosed methods such as method 100 instead change the properties of the LDCBS substrate material by forming oxygen precipitates in the sub-surface of the LDCBS substrate before exposure to high temperature processes such as the initial oxidation. Other advantages of disclosed embodiments include the ability to include a nucleation thermal (annealing) cycle in the initial oxidation recipe so that it does not add significant cycle time or cost. However, as disclosed above, the nucleation thermal (annealing) cycle and the initial oxidation can be performed as separate steps.

Disclosed embodiments may be used for a variety of processes including advanced analog processes with long process flows, such as linear BiCMOS. Moreover, standard CMOS processes can benefit where BMD growth can cause problems, particularly for CMOS technologies including laser/flash anneal processing.

### EXAMPLES

Disclosed embodiments are further illustrated by the following specific Examples, which should not be construed as limiting the scope or content of this Disclosure in any way.

FIG. 3 shows comparative BV results obtained from LDMOS transistors on test structures for completed IC product when a known annealing then initial oxidation step (shown as “Baseline”) was used and when a disclosed annealing then initial oxidation step was used shown as “Nucleation” (the example method with its temperature vs. time plot depicted in FIG. 2). One significant feature of the disclosed annealing then initial oxidation step is the nucleation portion which is at 650° C. in FIG. 2, between x-axis time units 0 and 2. For the Baseline annealing then initial oxidation step there is BV sensitivity shown for the 435° C. metal sintering step, where when the sintering time was doubled the standard BL sintering time (2×BL) for the devices processed with the BL annealing then initial oxidation step show a BV less than 50V (compared to around 900V with the baseline sinter time), while devices processed with the disclosed annealing then initial oxidation step shown as Nucleation showed a BV of nearly 800V, which is about the same BV results obtained for the Baseline sinter time.

Disclosed embodiments can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of semiconductor fabrication, comprising:
providing an unpatterned lightly doped Czochralski bulk silicon substrate (LDCBS substrate) having a concentration of oxygen atoms of at least (≧) 10¹⁷ atoms/cm³ with a boron doping or n-type doping concentration of between 1×10¹² cm⁻³ and 5×10¹⁴ cm⁻³;
before any oxidization processing, annealing said LDCBS substrate at a nucleating temperature between 550° C. and 760° C. for a nucleating time that nucleates said oxygen atoms in a sub-surface region of said LDCBS substrate to form oxygen precipitates therefrom, and
after said annealing, initially oxidizing a surface of said LDCBS substrate or an epitaxial layer on said surface of said LDCBS substrate in an oxidizing ambient at a peak temperature of between 800° C. and 925° C. for a time less than or equal (≦) to 30 minutes.

2. The method of claim 1, wherein said nucleating time is 1 to 3 hours.

3. The method of claim 1, wherein said nucleating temperature is between 575° C. and 690° C.

4. The method of claim 1, wherein said oxidizing ambient comprises steam.

5. The method of claim 1, wherein said annealing and said initially oxidizing are both performed as part of a common furnace cycle.

6. The method of claim 1, wherein said annealing is performed as a separate step before said initially oxidizing.

7. The method of claim 1, wherein said LDCBS substrate has said boron doping.

8. The method of claim 1, wherein said LDCBS substrate has said n-type doping.

9. The method of claim 1, wherein said nucleating temperature is from 640° C. to 690° C.

10. The method of claim 1, wherein said LDCBS substrate is an elemental silicon substrate.

11. A method of semiconductor fabrication, comprising:
providing an unpatterned lightly doped Czochralski bulk silicon substrate (LDCBS substrate) having a concentration of oxygen atoms of at least (≧) 10¹⁷ atoms/cm³ with a boron doping concentration between 1×10¹³ cm⁻³ and 5×10¹⁴ cm⁻³;
before any oxidization processing, annealing said LDCBS substrate at a nucleating temperature between 575° C. to 690° C. for a nucleating time that nucleates said oxygen atoms in a sub-surface region of said LDCBS substrate to form oxygen precipitates therefrom, and
after said annealing, initially oxidizing a surface of said LDCBS substrate or an epitaxial layer on said surface of said LDCBS substrate in steam at a peak temperature of between 875° C. and 925° C. for a time between 15 and 30 minutes.
